(19) United States
(12) Patent Application Publication
(10) Pub. No.: US 2023/0137784 A1
(43) Pub. Date: May 4, 2023

(54) DISPLAY DEVICE

(71) Applicant: Samsung Display Co., LTD., Yongin-si (KR)

(72) Inventors: Dong Hee SHIN, Asan-si (KR); Min Kyu WOO, Seoul (KR); Na Hyeon CHA, Yongin-si (KR)

(21) Appl. No.: 17/879,514

(22) Filed: Aug. 2, 2022

(30) Foreign Application Priority Data
Nov. 3, 2021 (KR) 10-2021-0149425

(51) Int. Cl. H01L 27/32

(52) U.S. Cl. CPC H01L 27/3276; H01L 27/3262; H01L 27/3265

(57) ABSTRACT

A display device includes first and second unit pixels adjacent to each other in a first direction, and each including first to third pixels, a first voltage line on a first side of each of the first and second unit pixels, and extended in a second direction crossing the first direction, a data line on a second side of each of the first and second unit pixels, and extended in the second direction, first gate lines between the first side of the first unit pixel and the second side of the second unit pixel to not be on the second side of the first unit pixel and to not be on the first side of the second unit pixel, and extended in the second direction, and a second gate line connected to at least one of the first gate lines, and extended in the first direction.

### CROSS-REFERENCE TO RELATED APPLICATION

This application claims priority to, and the benefit of, Korean Patent Application No. 10-2021-0149425 filed on Nov. 3, 2021 in the Korean Intellectual Property Office, the disclosure of which is incorporated herein by reference in its entirety.

### BACKGROUND

### 1. Field

The present disclosure relates to a display device.

### 2. Description of the Related Art

As the information-oriented society evolves, various demands for display devices are ever increasing. For example, display devices are being employed by a variety of electronic devices, such as smart phones, digital cameras, laptop computers, navigation devices, and smart televisions. Display devices may be flat panel display devices, such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel. A light-emitting element may be an organic light-emitting diode using an organic material as a fluorescent material or an inorganic light-emitting diode using an inorganic material as a fluorescent material.

### SUMMARY

Aspects of the present disclosure provide a display device that can obtain additional space for a display area to reduce RC delay, and that can have a driving margin.

It should be noted that aspects of the present disclosure are not limited to the above-mentioned aspect, and that other aspects of the present disclosure will be apparent to those skilled in the art from the following descriptions.

According to one or more embodiments of the disclosure, a display device includes first and second unit pixels adjacent to each other in a first direction, and each including first to third pixels, a first voltage line on a first side of each of the first and second unit pixels, and extended in a second direction crossing the first direction, a data line on a second side of each of the first and second unit pixels, and extended in the second direction, first gate lines between the first side of the first unit pixel and the second side of the second unit pixel to not be on the second side of the first unit pixel and to not be on the first side of the second unit pixel, and extended in the second direction, and a second gate line connected to at least one of the first gate lines, and extended in the first direction.

A number of first gate lines between the first unit pixel and the second unit pixel may be an odd number equal to or greater than three.

The first gate lines may be between the first voltage line connected to the first unit pixel and the data line connected to the second unit pixel.

The display device may further include third and fourth unit pixels arranged adjacent to each other in the first direction on the second side of the first unit pixel or on the first side of the second unit pixel, wherein other first gate lines are between a first side of the third unit pixel and a second side of the fourth unit pixel.

The first gate lines and the other first gate lines might not be between the second and third unit pixels.

A number of the other first gate lines between the third unit pixel and the fourth unit pixel may be an odd number equal to or greater than three.

The display device may further include an auxiliary gate line extended from the second gate line in the second direction and configured to supply a gate signal to the first to third pixels.

The display device may further include an initialization voltage line extended in the second direction between the auxiliary gate line and the data line and configured to supply an initialization voltage to the first to third pixels.

Each of the first to third pixels may include a light-emitting element, a first transistor between the first voltage line and the light-emitting element, and configured to supply a driving current to the light-emitting element, a second transistor configured to connect the data line with a first node coupled to a gate electrode of the first transistor based on the gate signal, a third transistor configured to connect the initialization voltage line with a second node coupled to a source electrode of the first transistor based on the gate signal, and a first capacitor connected between the first and second nodes.

The display device may further include a vertical voltage line on a second side of the data line, and extended in the second direction, and a second voltage line connected to the vertical voltage line, extended in the first direction, and configured to supply a low-level voltage to the light-emitting element.

According to one or more embodiments of the disclosure, a display device includes first and second unit pixels adjacent to each other in a first direction, and each including first to third pixels, a first voltage line in a first metal layer to extend in a second direction crossing the first direction, and configured to supply a driving voltage to the first to third pixels, a data line extended in the second direction in the first metal layer, first gate lines in the first metal layer, extended in the second direction between the first and second unit pixels, and not located on a first side of the second unit pixel that is not adjacent to the first unit pixel, and a second gate line in a second metal layer above the first metal layer, and extended in the first direction.

The display device may further include an auxiliary gate line extended from the second gate line in the second direction, and configured to supply gate signals to the first to third pixels, and an initialization voltage line extended in the first metal layer in the second direction, and configured to supply an initialization voltage to the first to third pixels.

Each of the first to third pixels may include a light-emitting element, a first transistor between the first voltage line and the light-emitting element, and configured to supply a driving current to the light-emitting element, a second transistor configured to connect the data line with a first node that is connected to a gate electrode of the first transistor based on one of the gate signals, a third transistor configured to connect the initialization voltage line with a second node that is connected to a source electrode of the first transistor based on the gate signal, and a first capacitor connected between the first and second nodes.

A gate electrode of each of the second and third transistors may correspond to a portion of the auxiliary gate line.

Each of the first to third transistors may include an active area, a drain electrode, a source electrode, and a gate electrode, wherein the active area, the drain electrode, and the source electrode are in an active layer between the first and second metal layers, and wherein the gate electrode is in the second metal layer.

The first capacitor may include a first capacitor electrode on the active layer, and connected to the first node, and a second capacitor electrode on the first metal layer, and connected to the second node.

The display device may further include first and second electrodes extended in the second direction in a third metal layer above the second metal layer, wherein the light-emitting element is aligned between the first and second electrodes when viewed from top.

The display device may further include a connection electrode in the second metal layer, and connected between the second node and the first electrode.

The display device may further include a second voltage line extended in the first direction in the second metal layer, wherein the second electrode is configured to receive a low-level voltage from the second voltage line.

The display device may further include a first contact electrode in a fourth metal layer above the third metal layer, and connected between a first end of the light-emitting element and the first electrode, and a second contact electrode in the fourth metal layer, and connected between a second end of the light-emitting element and the second electrode.

According to the disclosed embodiments of the present disclosure, vertical gate lines are located between a plurality of unit pixels and thus the number of the vertical gate lines can be reduced in a display device, so that additional space for a display area can be obtained. Accordingly, supply voltage lines or capacitors are located in the additionally obtained space for the display area in the display device, so that the RC delay can be reduced and the driving margin can be obtained.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view showing a display device according to one or more embodiments of the present disclosure.

FIG. 2 is a plan view showing contact points of vertical gate lines and horizontal gate lines in a display device according to one or more embodiments.

FIG. 3 is a view showing pixels and lines in a display device according to one or more embodiments.

FIG. 4 is a circuit diagram showing a pixel of a display device according to one or more embodiments of the present disclosure.

FIG. 5 is a plan view showing a part of a display area of a display device according to one or more embodiments of the present disclosure.

FIGS. 6 and 7 are enlarged views showing the thin-film transistor layer in area A1 of FIG. 5.

FIG. 8 is a cross-sectional view, taken along the line I-I′ of FIGS. 6 and 7.

FIG. 9 is a cross-sectional view, taken along the line II-II′ of FIGS. 6 and 7.

FIG. 10 is a plan view showing an emission material layer of a display device according to one or more embodiments of the present disclosure.

FIG. 11 is a cross-sectional view taken along the lines III-III′, IV-IV′, and V-V′ of FIG. 10.

FIG. 12 is a cross-sectional view taken along the line VI-VI′ of FIG. 10.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of one or more embodiments may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When one or more embodiments may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions might not reflect actual shapes of regions of a device and are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

Hereinafter, detailed embodiments of the present disclosure will be described with reference to the accompanying drawings.

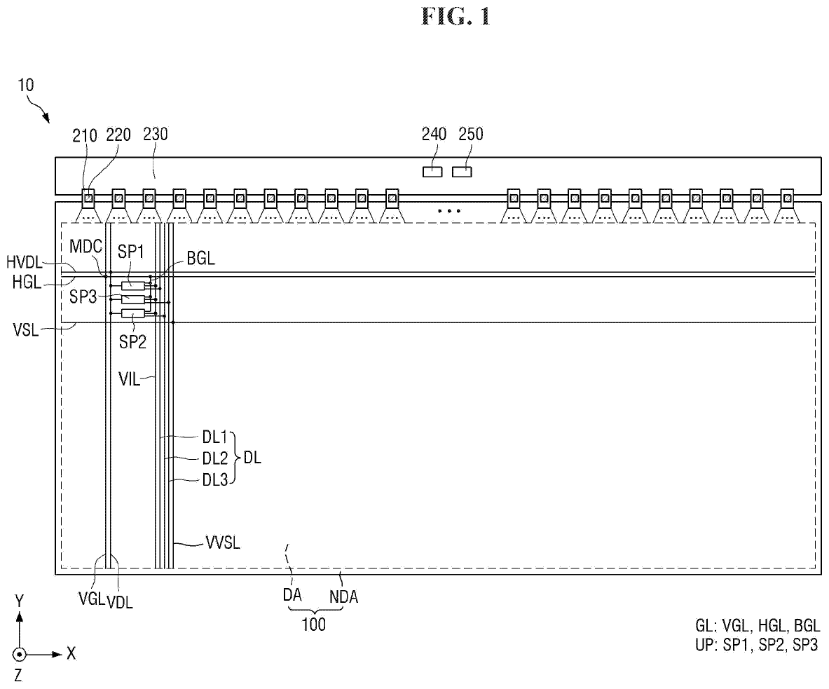

FIG. 1 is a plan view showing a display device according to one or more embodiments of the present disclosure.

As used herein, the terms “above,” “top” and “upper surface” refer to the upper side of the display device, i.e., the side indicated by the arrow of the z-axis direction, whereas the terms “below,” “bottom” and “lower surface” refer to the lower side of the display device, i.e., the opposite side in the z-axis direction. As used herein, the terms “left,” “right,” “upper” and “lower” sides indicate relative positions when the display device is viewed from the top. For example, the “left side” refers to the opposite side of the arrow of the x-axis, the “right side” refers to the side indicated by the arrow of the x-axis, the “upper side” refers to the side indicated by the arrow of the y-axis, and the “lower side” refers to the opposite side of the arrow of the y-axis.

Referring to FIG. 1, the display device is for displaying video or still image. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra-mobile PC (UMPC), as well as the display screen of various products such as a television, a laptop computer, a monitor, a billboard and the Internet of Things.

The display device may include a display panel 100, flexible films 210, display drivers (e.g., data drivers) 220, a circuit board 230, a timing controller 240, and a power supply 250.

The display panel 100 may have a rectangular shape when viewed from the top. For example, the display panel 100 may have a rectangular shape having longer sides in the first direction (x-axis direction) and shorter sides in the second direction (y-axis direction) when viewed from the top. The corners where the shorter sides in the first direction (x-axis direction) meet the longer sides in the second direction (y-axis direction) may be a right angle or may be rounded with a curvature (e.g., predetermined curvature). The shape of the display panel 100 when viewed from the top is not limited to a rectangular shape, but may be formed in a different polygonal shape, a circular shape, or an elliptical shape. For example, the display panel 100 may be formed flat, but the present disclosure is not limited thereto. For another example, the display panel 100 may be formed to bend with a curvature (e.g., predetermined curvature).

The display panel 100 may include a display area DA and non-display areas NDA.

The display area DA displays images therein, and may be generally defined as a central area of the display panel 100. The display area DA may include unit pixels UP, gate lines GL, data lines DL, initialization voltage lines VIL, first voltage lines VDL, horizontal voltage lines HVDL, vertical voltage lines VVSL, and second voltage lines VSL. The unit pixels UP may be formed in pixel areas that are crossing regions of the plurality of data lines DL and the plurality of gate lines GL, respectively. Each of the unit pixels UP may include first to third pixels SP1, SP2, and SP3. Each of the first to third sub-pixels SP1, SP2, and SP3 may be connected to one horizontal gate line HGL and one data line DL. Each of the first to third pixels SP1, SP2, and SP3 may be defined as the minimum unit area that emits light.

The first pixel SP1 may emit light of a first color or red light, the second pixel SP2 may emit light of a second color or green light, and the third pixel SP3 may emit light of a third color or blue light. The pixel circuit of the first pixel SP1, the pixel circuit of the third pixel SP3, and the pixel circuit of the second pixel SP2 may be arranged in the direction opposite to the second direction (y-axis direction). It should be understood, however, that the present disclosure is not limited thereto.

The gate lines GL may include vertical gate lines VGL, horizontal gate lines HGL, and auxiliary gate lines BGL.

The plurality of vertical gate lines VGL may be connected to the display drivers 220, may extend in the second direction (y-axis direction), and may be spaced apart from one another in the first direction (x-axis direction). The vertical gate lines VGL may be first gate lines. The vertical gate lines VGL may be arranged to be substantially parallel with the data lines DL. The plurality of horizontal gate lines HGL may extend in the first direction (x-axis direction), and may be spaced apart from one another in the second direction (y-axis direction). The horizontal gate lines HGL may be second gate lines. The plurality of horizontal gate lines HGL may cross the plurality of vertical gate lines VGL. For example, one horizontal gate line HGL may be connected to one vertical gate line VGL among the plurality of vertical gate lines VGL through a contact point MDC. At the contact point MDC, a portion of the horizontal gate line HGL may be inserted into a contact hole, and may be in contact with the vertical gate line VGL. The auxiliary gate lines BGL may extend from the horizontal gate lines HGL to supply gate signals to the first to third sub-pixels SP1, SP2, and SP3, respectively. The plurality of data lines DL may extend in the second direction (y-axis direction), and may be spaced apart from each other in the first direction (x-axis direction). The plurality of data lines DL may include first to third data lines DL1, DL2, and DL3. The first to third data lines DL1, DL2, and DL3 may supply data voltage to the first to third pixels SP1, SP2, and SP3, respectively.

The plurality of initialization voltage line VIL may extend in the second direction (y-axis direction), and may be spaced apart from each other in the first direction (x-axis direction). The initialization voltage lines VIL may supply the initialization voltage received from the display driver 220 to the pixel circuit of each of the first to third sub-pixels SP1, SP2, and SP3. The initialization voltage line VIL may receive a sensing signal from the pixel circuit of each of the first to third pixels SP1, SP2, and SP3, and may supply the sensing signal to the display driver 220.

The plurality of first voltage line VDL may extend in the second direction (y-axis direction), and may be spaced apart from each other in the first direction (x-axis direction). The first voltage line VDL may supply a driving voltage or a high-level voltage received from the power supply 250 to the first to third pixels SP1, SP2, and SP3.

The plurality of horizontal gate lines HVDL may extend in the first direction (x-axis direction) and may be spaced apart from one another in the second direction (y-axis direction). The horizontal voltage lines HVDL may be connected to the first voltage lines VDL. The horizontal voltage lines HVDL may supply the driving voltage or high-level voltage to the first voltage lines VDL.

The vertical voltage lines VVSL may extend in the second direction (y-axis direction) and may be spaced apart from each other in the first direction (x-axis direction). The vertical voltage lines VVSL may be connected to the second voltage lines VSL. The vertical voltage lines VVSL may supply the low-level voltage received from the power supply 250 to the second voltage lines VSL.

The second voltage lines VSL may extend in the first direction (x-axis direction), and may be spaced apart from each other in the second direction (y-axis direction). The second voltage lines VSL may supply a low-level voltage to the first to third sub-pixels SP1, SP2, and SP3.

The connection relationship of the unit pixels UP, the gate lines GL, the data lines DL, the initialization voltage lines VIL, the first voltage lines VDL and the second voltage lines VSL may be altered depending on the number and arrangement of the unit pixels UP

The non-display area NDA may be defined as the remaining area of the display panel 100 that excludes the display area DA. For example, the non-display area NDA may include fan-out lines connecting the vertical gate lines VGL, the data lines DL, the initialization voltage lines VIL, the first voltage lines VDL, and the vertical voltage lines VVSL with the display drivers 220, and a pad area connected to the flexible films 210.

The input terminals located on one side of the flexible films 210 may be attached to the circuit board 230 via a film attaching process, and the output terminals provided on the other side of the flexible films 210 may be attached to the pad area via the film attaching process. For example, each of the flexible films 210 may be a flexible film that can be bent, such as a tape carrier package and a chip on film. The flexible films 210 may be bent so that they are located under the display panel 100 to reduce the bezel area of the display device.

The display drivers 220 may be mounted on the flexible films 210, respectively. For example, the display drivers 220 may be implemented as integrated circuits (IC). The display drivers 220 may receive digital video data and a data control signal from the timing controller 240, and may convert the digital video data into an analog data voltage in response to the data control signal to send it to the data lines DL through the fan-out lines. The display drivers 220 may generate gate signals in response to a gate control signal supplied from the timing controller 240, and may sequentially supply the gate signals to the plurality of vertical gate lines VGL in an order (e.g., predetermined order). Accordingly, the display drivers 220 may work as data drivers as well as gate drivers. Because the display device 10 includes the display drivers 220 located on the upper side of the non-display area NDA, sizes of the left, right, and lower sides of the non-display area NDA can be reduced.

The circuit board 230 may support the timing controller 240 and the power supply 250, and may supply signals and voltages to the display drivers 220. For example, the circuit board 230 may supply a signal supplied from the timing controller 240, and may supply voltages supplied from the power supply 250 to the display drivers 220 to drive the pixels to display images. To this end, a signal transmission line and a voltage line may be located on the circuit board 230.

The timing controller 240 may be mounted on the circuit board 230, and may receive image data and a timing synchronization signal supplied from a display driving system or a graphic device through a user connector provided on the circuit board 230. The timing controller 240 may generate digital video data by coordinating the image data appropriately for the pixel arrangement structure in response to a timing synchronization signal, and may supply the generated digital video data to the display driver 220. The timing controller 240 may generate a data control signal and a gate control signal based on the timing synchronization signal. The timing controller 240 may control the supply timing of the data voltage of the display driver 220 based on the data control signal, and may control the supply timing of the gate signal of the display driver 220 based on the gate control signal.

The power supply 250 may be located on the circuit board 230 to apply a supply voltage to the display drivers 220 and the display panel 100. For example, the power supply 250 may generate a driving voltage or a high-level voltage to supply it to the first voltage lines VDL, may generate a low-level voltage to supply it to the vertical voltage lines VVSL, and may generate an initialization voltage to supply it to the initialization voltage lines.

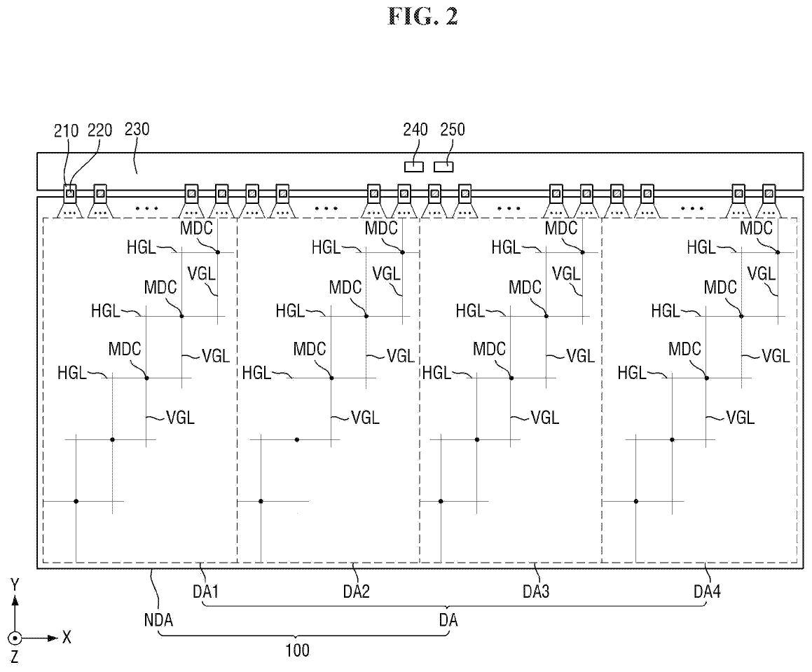

FIG. 2 is a plan view showing contact points of vertical gate lines and horizontal gate lines in a display device according to one or more embodiments.

Referring to FIG. 2, the display area DA may include first to fourth display area DA1, DA2, DA3, and DA4.

The plurality of horizontal gate lines HGL may cross the plurality of vertical gate lines VGL, respectively. For example, one horizontal gate line HGL may be connected to one vertical gate line VGL among the plurality of vertical gate lines VGL through a contact point MDC. The horizontal gate line HGL may be insulated from the other vertical gate lines VGL. Accordingly, the horizontal gate lines HGL and the vertical gate lines VGL may be insulated from each other at crossing regions, with the exception of the contact points MDC.

The contact points MDC of the first display area DA1 may be generally arranged on a line extended from the upper right side of the first display area DA1 to the lower left side of the first display area DA1. The contact points MDC of the second display area DA2 may be generally arranged on a line extended from the upper right side of the second display area DA2 to the lower left side of the second display area DA2. The contact points MDC of the third display area DA3 may be generally arranged on a line extended from the upper right side of the third display area DA3 to the lower left side of the third display area DA3. The contact points MDC of the fourth display area DA4 may be generally arranged on a line extended from the upper right side of the fourth display area DA4 to the lower left side of the fourth display area DA4. Accordingly, the plurality of contact points MDC may be generally arranged in a diagonal direction between the first direction (x-axis direction) and the second direction (y-axis direction) in each of the first to fourth display areas DA1, DA2, DA3, and DA4.

The display device 10 may include the display drivers 220 working as data drivers as well as gate drivers. Accordingly, the data lines DL may receive data voltages from the display drivers 220 located on the upper side of the non-display area NDA, and the vertical gate lines GL may receive gate signals from the display drivers 220 located on the upper side of the non-display area NDA, so that the sizes of the left, right and lower sides of the non-display area NDA of the display device 10 can be reduced.

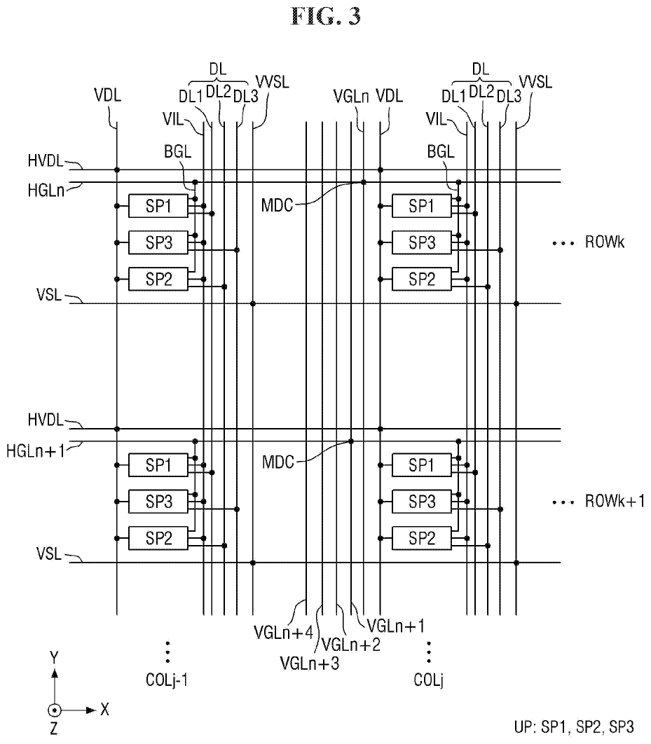

FIG. 3 is a view showing pixels and lines in a display device according to one or more embodiments.

Referring to FIG. 3, the unit pixel UP may include first to third pixels SP1, SP2, and SP3. The pixel circuit of the first pixel SP1, the pixel circuit of the third pixel SP3 and the pixel circuit of the second pixel SP2 may be arranged in the direction opposite to the second direction (y-axis direction). It should be understood, however, that the present disclosure is not limited thereto.

Each of the first to third sub-pixels SP1, SP2, and SP3 may be connected to the first voltage lines VDL, the initialization voltage lines VIL, the gate lines GL and the data lines DL.

The first voltage lines VDL may extend in the second direction (y-axis direction). The first voltage lines VDL may be located on one side (e.g., a first side, or the left side) of the pixel circuits of the first to third pixels SP1, SP2, and SP3. The first voltage lines VDL may supply a driving voltage or a high-level voltage to transistors of each of the first to third pixels SP1, SP2, and SP3.

The horizontal voltage lines HVDL may extend in the first direction (x-axis direction). The horizontal voltage lines HVDL may be located on the upper side of the horizontal gate lines HGL, respectively. The horizontal voltage lines HVDL may be connected to the first voltage lines VDL. The horizontal voltage lines HVDL may supply the driving voltage or high-level voltage to the first voltage lines VDL.

An initialization voltage line VIL may extend in the second direction (y-axis direction). The initialization voltage line VIL may be located on the opposite side (e.g., other side, the right side, or a second side) of the auxiliary gate line BGL. The initialization voltage line VIL may be located between the auxiliary gate line BGL and the data line DL. The initialization voltage line VIL may supply the initialization voltage to the pixel circuit of each of the first to third pixels SP1, SP2, and SP3. The initialization voltage lines VIL may receive a sensing signal from the pixel circuit of each of the first to third pixels SP1, SP2, and SP3, and may supply the sensing signal to the display drivers 220.

The gate lines GL may include vertical gate lines VGL, horizontal gate lines HGL, and auxiliary gate lines BGL.

The vertical gate lines VGL may extend in the second direction (y-axis direction). Each of the vertical gate lines VGL may be located between adjacent unit pixels UP. The vertical gate lines VGL may be connected between the display driver 220 and the horizontal gate lines HGL. The plurality of vertical gate lines VGL may cross the plurality of horizontal gate lines HGL. The vertical gate lines VGL may supply the gate signals received from the display drivers 220 to the horizontal gate lines HGL.

For example, the nth vertical gate line VGLn, the (n+1)^{th} vertical gate line VGL(n+1), the (n+2)^{th} vertical gate line VGL(n+2), the (n+3)^{th} vertical gate line VGL(n+3), and the (n+4)^{th} vertical gate line VGL(n+4) may be located between a unit pixel UP located in the jth column COLj and a unit pixel UP located in the (j−1)^{th} column COL(j−1), where n and j are positive integers. The plurality of vertical gate lines VGL may be arranged in parallel between the data line DL connected to respective ones of the unit pixels UP located on one side and the first voltage line VDL connected to the respective ones of the unit pixels UP located on the opposite side. The n^{th}, the (n+1)^{th}, the (n+2)^{th}, the (n+3)^{th}, and the (n+4)^{th} vertical gate lines VGLn, VGL(n+1), VGL(n+2), VGL(n+3), and VGL(n+4) may be located between the data line DL connected to the unit pixel UP located in the (j−1)^{th} column COL(j−1), and the first voltage line VDL connected to the unit pixel UP located in the j^{th} column COLj. The n^{th} vertical gate line VGLn may be connected to the n^{th} horizontal gate line HGLn through the corresponding contact point MDC, and may be insulated from the other horizontal gate lines HGL. The (n+1)^{th} vertical gate line VGL(n+1) may be connected to the (n+1)^{th} horizontal gate line HGL(n+1) through the corresponding contact point MDC and may be insulated from the other horizontal gate lines HGL.

The horizontal gate lines HGL may extend in the first direction (x-axis direction). The horizontal gate lines HGL may be located on the upper side of the pixel circuit of the first pixels SP1. The horizontal gate lines HGL may be connected between the vertical gate lines VGL and the auxiliary gate lines BGL. The horizontal gate lines HGL may supply gate signals received from the vertical gate lines VGL to the auxiliary gate lines BGL.

For example, the n^{th} horizontal gate line HGLn may be located on the upper side of (e.g., above in plan view) the pixel circuit of the first pixel SP1 located in the kth row ROWk, where k is a positive integer. The n^{th} horizontal gate line HGLn may be connected to the n^{th} vertical gate line VGLn through the contact point MDC, and may be insulated from the other vertical gate lines VGL. The (n+1)^{th} horizontal gate line HGL(n+1) may be above the pixel circuit of the first pixel SP1 located in the (k+1)^{th} row ROW(k+1). The (n+1)^{th} horizontal gate line HGL(n+1) may be connected to the (n+1)^{th} vertical gate line VGL(n+1) through the contact point MDC, and may be insulated from the other vertical gate lines VGL.

The auxiliary gate lines BGL may extend in the direction that is opposite to the second direction/y-axis direction (e.g., downwardly in plan view) from the horizontal gate lines HGL. The auxiliary gate lines BGL may be located on the right side of the pixel circuits of the first to third pixels SP1, SP2, and SP3. The auxiliary gate lines BGL may supply the gate signals received from the horizontal gate lines HGL to the pixel circuits of the first to third pixels SP1, SP2, and SP3.

The plurality of data lines DL may extend in the second direction (y-axis direction). The plurality of data lines DL may supply data voltage to each of the plurality of pixels SP. The plurality of data lines DL may include first to third data lines DL1, DL2, and DL3.

The first data line DL1 may extend in the second direction (y-axis direction). The first data line DL1 may be located on the opposite side (e.g., the right side) of the initialization voltage line VIL. The first data line DL1 may supply the data voltage received from the display driver 220 to the pixel circuit of the first pixel SP1.

The second data line DL2 may extend in the second direction (y-axis direction). The second data line DL2 may be located on the opposite side/right side of the first data line DL1. The second data line DL2 may supply the data voltage received from the display driver 220 to the pixel circuit of the second pixel SP2.

The third data line DL3 may extend in the second direction (y-axis direction). The third data line DL3 may be located on the opposite side/right side of the second data line DL2. The third data line DL3 may supply the data voltage received from the display driver 220 to the pixel circuit of the third pixel SP3.

The vertical voltage line VVSL may extend in the second direction (y-axis direction). The vertical voltage line VVSL may be located on the other side/right side of the third data line DL3. The vertical voltage line VVSL may be connected between the power supply 250 and the second voltage line VSL. The vertical voltage line VVSL may supply the low-level voltage supplied from the power supply 250 to the second voltage line VSL.

A second voltage line VSL may extend in the first direction (x-axis direction). The second voltage line VSL may be located on the lower side of (e.g., below) the pixel circuit of the second pixel SP2. The second voltage line VSL may supply the low-level voltage received from the vertical voltage line VVSL to the light-emitting element layer of the first to third pixels SP1, SP2, and SP3.

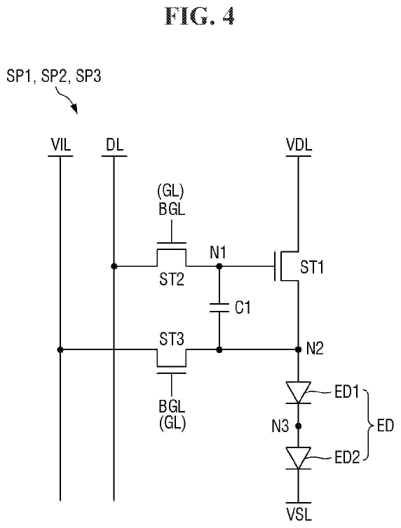

FIG. 4 is a circuit diagram showing a pixel of a display device according to one or more embodiments of the present disclosure.

Referring to FIG. 4, each of the plurality of pixels SP may be connected to a first voltage line VDL, a data line DL, an initialization voltage line VIL, an auxiliary gate line BGL, and a second voltage line VSL.

Each of the first to third pixels SP1, SP2, and SP3 may include first to third transistors ST1, ST2, and ST3, a first capacitor C1, and a plurality of light-emitting elements ED.

The first transistor ST1 may include a gate electrode, a drain electrode, and a source electrode. The gate electrode of the first transistor ST1 may be connected to a first node N1, the drain electrode thereof may be connected to the first voltage line VDL, and the source electrode thereof may be connected to a second node N2. The first transistor ST1 may control a drain-source current (or a driving current) based on a data voltage applied to the gate electrode.

The light-emitting elements ED may include first light-emitting diodes ED1 and second light-emitting diodes ED2. The first and second light-emitting elements ED1 and ED2 may be connected in series. The first and second light-emitting elements ED1 and ED2 may receive a driving current to emit light. The amount or the brightness of the light emitted from the light-emitting elements ED may be proportional to the magnitude of the driving current. The light-emitting elements ED may be, but is not limited to, inorganic light-emitting elements including an inorganic semiconductor.

A first electrode of the first light-emitting element ED1 may be connected to the second node N2, and a second electrode of the first light-emitting element ED1 may be connected to a third node N3. The first electrode of the first light-emitting element ED1 may be connected to the source electrode of the first transistor ST1, the source electrode of the third transistor ST3, and the second electrode of the first capacitor C1 through the second node N2. The second electrode of the first light-emitting element ED1 may be connected to the first electrode of the second light-emitting element ED2 through the third node N3.

A first electrode of the second light-emitting element ED2 may be connected to the third node N3, and a second electrode of the second light-emitting element ED2 may be connected to the second voltage line VSL. The first electrode of the second light-emitting element ED2 may be connected to the second electrode of the first light-emitting element ED1 through the third node N3.

The second transistor ST2 may be turned on by a gate signal from the auxiliary gate line BGL or the gate line GL to connect the data line DL with the first node N1, which is the gate electrode of the first transistor ST1. The second transistor ST2 may be turned on in response to the gate signal to apply a data voltage to the first node N1. The gate electrode of the second transistor ST2 may be connected to the auxiliary gate line BGL, the drain electrode may be connected to the data line DL, and the source electrode may be connected to the first node N1. The source electrode of the second transistor ST2 may be connected to the gate electrode of the first transistor ST1 and the first capacitor electrode of the first capacitor C1 through the first node N1.

The third transistor ST3 may be turned on by a gate signal of an auxiliary gate line BGL or a gate line GL to connect the initialization voltage line VIL with the second node N2, which is the source electrode of the first transistor ST1. The third transistor ST3 may be turned on in response to the gate signal to apply the initialization voltage to the second node N2. The gate electrode of the third transistor ST3 may be connected to the auxiliary gate line BGL, the drain electrode may be connected to the initialization voltage line VIL, and the source electrode may be connected to the second node N2. The source electrode of the third transistor ST3 may be connected to the source electrode of the first transistor ST1 through the second node N2, to the second capacitor electrode of the first capacitor C1, and to the first electrode of the first light-emitting element ED1.

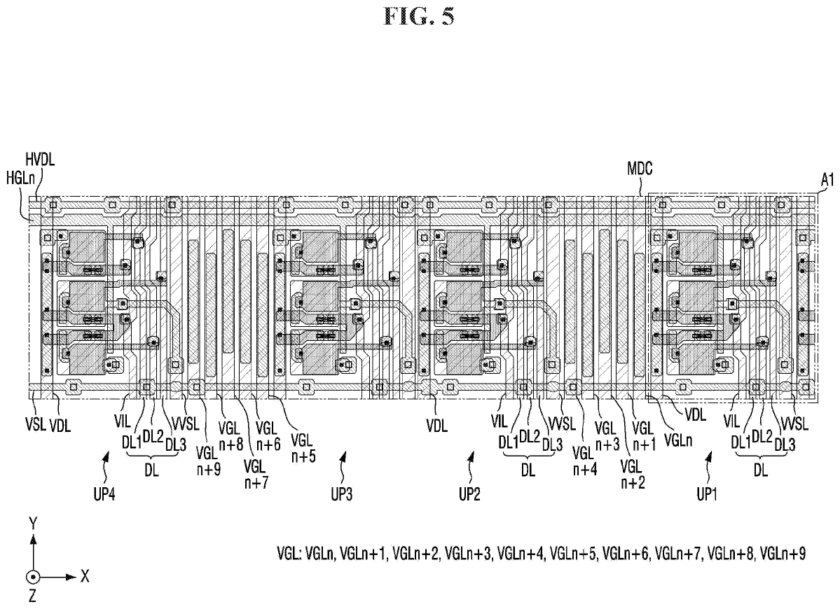

FIG. 5 is a plan view showing a part of a display area of a display device according to one or more embodiments of the present disclosure.

Referring to FIG. 5, the display area DA may include unit pixels UP, gate lines GL, data lines DL, initialization voltage lines VIL, first voltage lines VDL, horizontal voltage lines HVDL, vertical voltage lines VVSL, and second voltage lines VSL. The unit pixels UP may include first to fourth unit pixels UP1, UP2, UP3, and UP4 arranged in the first direction (x-axis direction). The gate lines GL may include vertical gate lines VGL, horizontal gate lines HGL, and auxiliary gate lines BGL.

The plurality of vertical gate lines VGL may be located on one side (e.g., the left side) of some unit pixels UP among the plurality of unit pixels UP. The plurality of vertical gate lines VGL may be located between some unit pixels UP among the plurality of unit pixels UP. For example, the n^{th}, (n+1)^{th} (n+2)^{th}, (n+3)^{th}, and (n+4)^{th} vertical gate lines VGLn, VGL(n+1), VGL(n+2), VGL(n+3), and VGL(n+4) may be located on one side/the left side of the first unit pixel UP1. The vertical gate lines VGL might not be located on the opposite side (e.g., the right side) of the first unit pixel UP1. The vertical gate lines VGL might not be located on one side/the left side of the second unit pixel UP2 (e.g., might not be between the second unit pixel UP2 and a third unit pixel UP3 that is located to the left of the second unit pixel UP2). The n^{th}, the (n+1)^{th}, the (n+2)^{th}, the (n+3)^{th}, and the (n+4)^{th} vertical gate lines VGLn, VGL(n+1), VGL(n+2), VGL(n+3), and VGL(n+4) may be located between the first and second unit pixels UP1 and UP2. The vertical gate lines VGL might not be located between the second and third unit pixels UP2 and UP3.

The (n+5)^{th}, (n+6)^{th}, (n+7)^{th}, (n+8)^{th}, and (n+9)^{th} vertical gate lines VGL(n+5), VGL(n+6), VGL(n+7), VGL(n+8), and VGL(n+9) may be located on one side (e.g., the left side) of the third unit pixel UP3. These vertical gate lines VGL might not be located on the opposite side (e.g., the right side) of the third unit pixel UP3. The vertical gate lines VGL might not be located on one side/the left side of the fourth unit pixel UP4. The (n+5)^{th}, (n+6)^{th}, (n+7)^{th}, (n+8)^{th}, and (n+9)^{th} vertical gate lines VGL(n+5), VGL(n+6), VGL(n+7), VGL(n+8), and VGL(n+9) may be located between the third and fourth unit pixels UP3 and UP4. The vertical gate lines VGL might not be located between the second and third unit pixels UP2 and UP3.

The display device 10 may include an odd number of vertical gate lines VGL located between some unit pixels UP among the plurality of unit pixels UP. The vertical gate lines VGL may be located between a plurality of unit pixels UP. For example, five vertical gate lines VGL are located between some unit pixels UP, and thus the number of the vertical gate lines VGL can be reduced compared to the structure where three vertical gate lines VGL are located at one side of each of the plurality of unit pixels UP. In this manner, the number of the vertical gate lines VGL can be reduced in the display device 10 so that the space of the display area DA can be additionally obtained. The supply voltage lines or the capacitors can be located in the additionally obtained space in the display area DA, and thus the RC delay can be reduced and driving margin can be obtained.

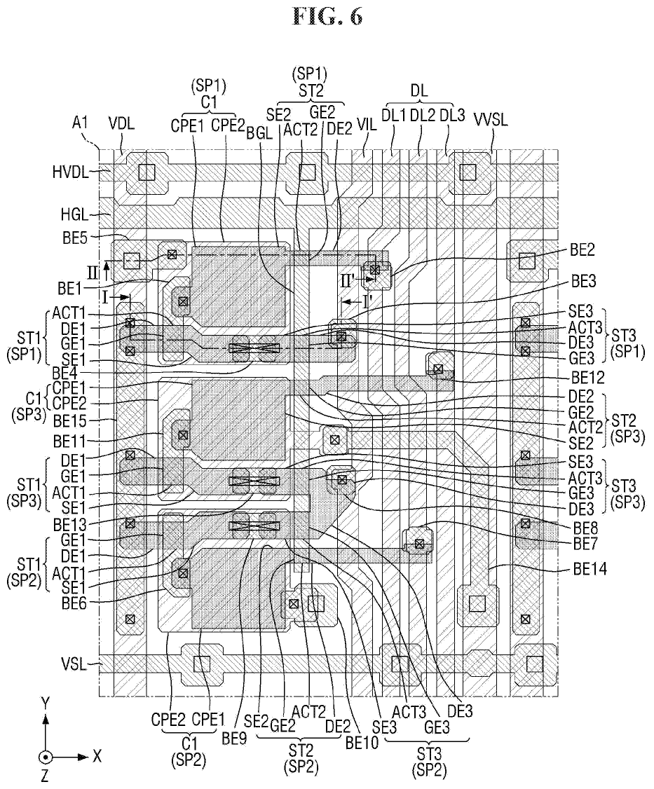

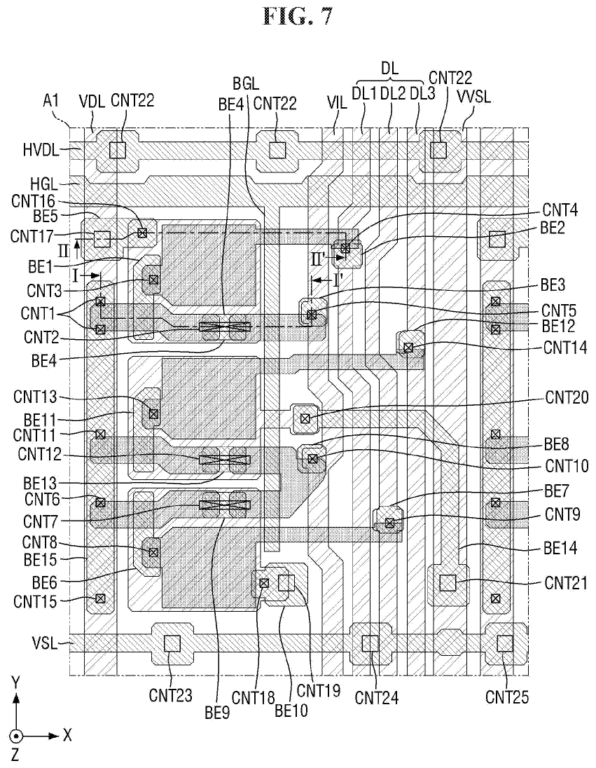

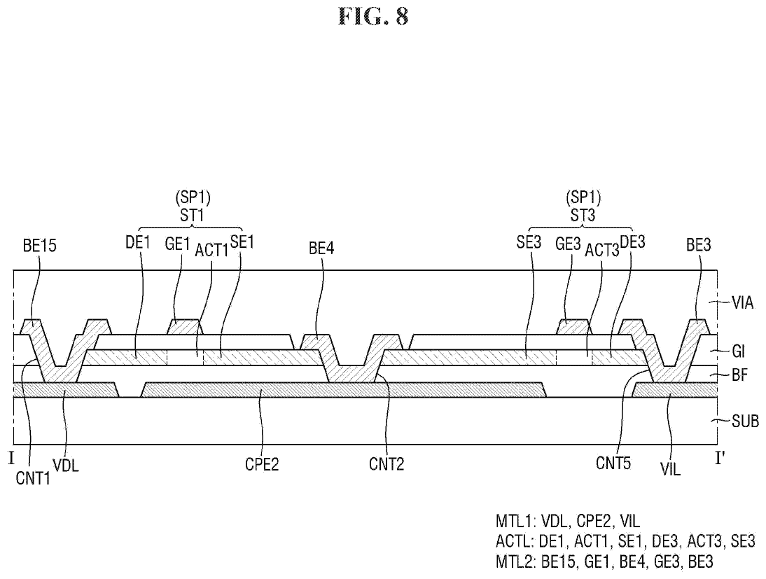

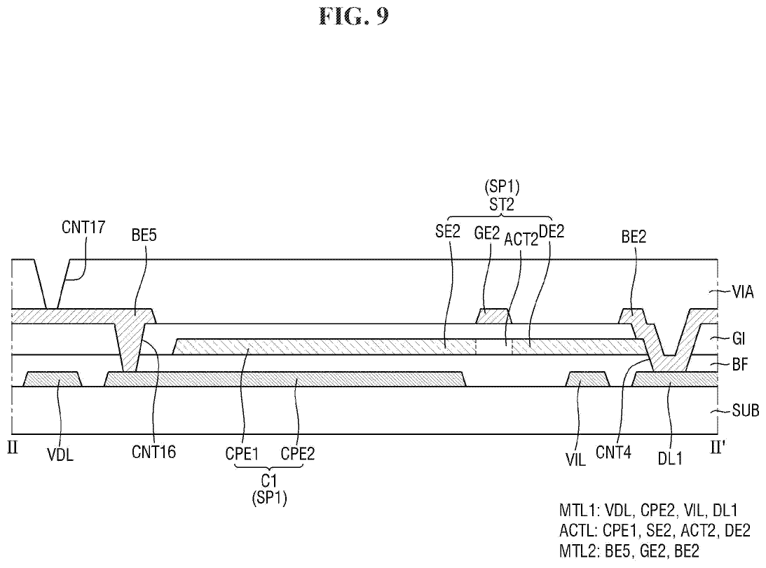

FIGS. 6 and 7 are enlarged views showing the thin-film transistor layer in area A1 of FIG. 5. FIG. 8 is a cross-sectional view, taken along the line I-I′ of FIGS. 6 and 7. FIG. 9 is a cross-sectional view, taken along the line II-II′ of FIGS. 6 and 7.

Referring to FIGS. 6 to 9, the unit pixel UP may include first to third pixels SP1, SP2, and SP3. The pixel circuit of the first pixel SP1, the pixel circuit of the third pixel SP3, and the pixel circuit of the second pixel SP2 may be arranged in the direction opposite to the second direction/y-axis direction (e.g., from top to bottom). The pixel circuit of each of the first to third pixels SP1, SP2, and SP3 may be located in the pixel area.

The first voltage line VDL may be at a first metal layer MTL1 on the substrate

SUB. The first voltage line VDL may be located on one side or the left side of the pixel circuits of the first to third pixels SP1, SP2, and SP3. The first voltage line VDL may overlap a fifteenth connection electrode BE15 of a second metal layer MTL2 in the thickness direction (z-axis direction). The first voltage line VDL may be connected to the fifteenth connection electrode BE15 through the fifteenth contact hole CNT15. The fifteenth connection electrode BE15 may be connected to the drain electrode DE1 of the first transistor ST1 of the first pixel SP1 through a first contact hole CNT1, to the drain electrode DE1 of the first transistor ST1 of the second pixel SP2 through a sixth contact hole CNT6, and to the drain electrode DE1 of the first transistor ST1 of the third pixel SP3 through an eleventh contact hole CNT11. Accordingly, the first voltage line VDL may supply a driving voltage to the first to third pixels SP1, SP2, and SP3 through the fifteenth connection electrode BE15.

The horizontal voltage line HVDL may be at the second metal layer MTL2. The second metal layer MTL2 may be located on a gate insulator GI covering the active layer ACTL. The horizontal voltage line HVDL may be located above the horizontal gate line HGL (e.g., in plan view). The horizontal voltage line HVDL may be connected to the plurality of first voltage lines VDL to receive a driving voltage. The horizontal voltage line HVDL can stably maintain the driving voltage or high-level voltage of the plurality of first voltage lines VDL.

The initialization voltage line VIL may be at the first metal layer MTL. The initialization voltage line VIL may be located on the opposite side/the right side of the auxiliary gate line BGL. A third connection electrode BE3 of the second metal layer MTL2 may connect the initialization voltage line VIL with a drain electrode DE3 of the third transistor ST3 of the first pixel SP1 through a fifth contact hole CNT5. An eighth connection electrode BE8 of the second metal layer MTL2 may connect the initialization voltage line VIL with the drain electrode DE3 of the third transistor ST3 of the second pixel SP2 through a tenth contact hole CNT10. The eighth connection electrode BE8 may connect the initialization voltage line VIL with the drain electrode DE3 of the third transistor ST3 of the third pixel SP3 through the tenth contact hole CNT10. The drain electrode DE3 of the third transistor ST3 of the second pixel SP2 and the drain electrode DE3 of the third transistor ST3 of the third pixel SP3 may be integrally formed, but the present disclosure is not limited thereto. Accordingly, the initialization voltage line VIL may supply an initialization voltage to the third transistor ST3 of each of the first to third pixels SP1, SP2, and SP3, and may receive a sensing signal from the third transistor ST3.

The horizontal gate line HGL may be at the second metal layer MTL2. The horizontal gate lines HGL may be located on the upper side of (e.g., above, in plan view) the pixel circuit of the first pixels SP1. The horizontal gate line HGL may be connected to the vertical gate line VGL located on the first metal layer MTL1 through the contact point MDC. The horizontal gate line HGL may supply a gate signal received from the vertical gate line VGL to the auxiliary gate line BGL.

The auxiliary gate lines BGL may be at the second metal layer MTL2. The auxiliary gate lines BGL may protrude from the horizontal gate lines HGL in the direction opposite to the second direction (y-axis direction). The auxiliary gate lines BGL may be formed integrally with the horizontal gate lines HGL, but the present disclosure is not limited thereto. The auxiliary gate line BGL may be located on the opposite side/the right side of the pixel circuits of the first to third pixels SP1, SP2, and SP3. The auxiliary gate lines BGL may supply the gate signals received from the horizontal gate lines HGL to the second and third transistors ST2 and ST3 of each of the first to third pixels SP1, SP2, and SP3.

The first data line DL1 may be at the first metal layer MTL1. The first data line DL1 may be located on the opposite side/the right side of the initialization voltage line VIL. A second connection electrode BE2 of the second metal layer MTL2 may connect the first data line DL1 with a drain electrode DE2 of the second transistor ST2 of the first pixel SP1 through a fourth contact hole CNT4. The first data line DL1 may supply the data voltage to the second transistor ST2 of the first pixel SP1.

The second data line DL2 may be at the first metal layer MTL1. The second data line DL2 may be located on the opposite side/the right side of the first data line DL1. A seventh connection electrode BE7 of the second metal layer MTL2 may connect the second data line DL2 with the drain electrode DE2 of the second transistor ST2 of the second pixel SP2 through a ninth contact hole CNT9. The second data line DL2 may supply the data voltage to the second transistor ST2 of the second pixel SP2.

The third data line DL3 may be at the first metal layer MTL1. The third data line DL3 may be located on the opposite side/the right side of the second data line

DL2. A twelfth connection electrode BE12 of the second metal layer MTL2 may connect the third data line DL3 with the drain electrode DE2 of the second transistor ST2 of the third pixel SP3 through a fourteenth contact hole CNT14. The third data line DL3 may supply the data voltage to the second transistor ST2 of the third pixel SP3.

The vertical voltage line VVSL may be at the first metal layer MTL1. The vertical voltage line VVSL may be located on the opposite side/the right side of the third data line DL3. The vertical voltage line VVSL may be connected to the second voltage line VSL of the second metal layer MTL2. The vertical voltage line VVSL may supply a low-level voltage to the second voltage line VSL.

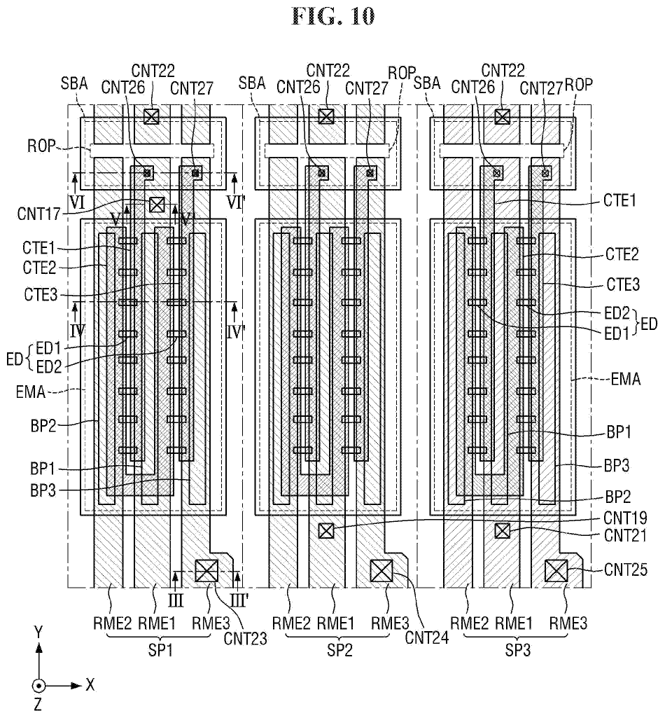

The second voltage line VSL may be at the second metal layer MTL2. The second voltage line VSL may be located on the lower side of (e.g., below, in plan view) the pixel circuit of the second pixel SP2. The second voltage line VSL may supply the low-level voltage received from the vertical voltage line VVSL to the third electrode of each of the first to third pixels SP1, SP2, and SP3. For example, the second voltage line VSL may be connected to the third electrode of the first pixel SP1 through a twenty-third contact hole CNT23. The second voltage line VSL may be connected to the third electrode of the second pixel SP2 through a twenty-fourth contact hole CNT24. The second voltage line VSL may be connected to a third electrode RME3 of the third pixel SP3 through a twenty-fifth contact hole CNT25 (e.g., see FIG. 10). The third electrode of each of the first to third pixels SP1, SP2, and SP3 may be located on the third electrode layer, and the twenty-third to twenty-fifth contact holes CNT23, CNT24, and CNT25 may be formed through the via layer VIA. The via layer VIA may be located on, or above, the second metal layer MTL2 and the gate insulator GI (e.g., in a thickness direction/z-axis direction).

The pixel circuit of the first pixel SP1 may include the first to third transistors ST1, ST2, and ST3. The first transistor ST1 of the first pixel SP1 may include an active area ACT1, a gate electrode GE1, a drain electrode DE1, and a source electrode SE1. The active area ACT1 of the first transistor ST1 may be located in the active layer ACTL, and may overlap with the gate electrode GE1 of the first transistor ST1 in the thickness direction (z-axis direction). The active layer ACTL may be located on the buffer layer BF covering the first metal layer MTL1.

The gate electrode GE1 of the first transistor ST1 may be located in the second metal layer MTL2. The gate electrode GE1 of the first transistor ST1 may be connected to the first capacitor electrode CPE1 of the first capacitor C1 located in the active layer ACTL through a third contact hole CNT3. The first capacitor electrode CPE1 of the first capacitor C1 may be formed into a conductor by heat-treating the active layer ACTL. The first capacitor electrode CPE1 of the first capacitor C1 may be formed integrally with the source electrode SE2 of the second transistor ST2, but the present disclosure is not limited thereto.

The drain electrode DE1 and the source electrode SE1 of the first transistor ST1 may be formed into a conductor by heat-treating the active layer ACTL. The fifteenth connection electrode BE15 may connect the first voltage line VDL with the drain electrode DE1 of the first transistor ST1 through the first contact hole CNT1. The drain electrode DE1 of the first transistor ST1 may receive a driving voltage from the first voltage line VDL.

A fourth connection electrode BE4 of the second metal layer MTL2 may connect the source electrode SE1 of the first transistor ST1, the source electrode SE3 of the third transistor ST3, and the second capacitor electrode CPE2 of the first metal layer MTL1 through a second contact hole CNT2. The first capacitor C1 may include the first capacitor electrode CPE1 of the active layer ACTL and the second capacitor electrode CPE2 of the first metal layer MTL1.

A fifth connection electrode BE5 of the second metal layer MTL2 may be connected to the second capacitor electrode CPE2 through a sixteenth contact hole CNT16. The fifth connection electrode BE5 may be connected to the first electrode of the first pixel SP1 through a seventeenth contact hole CNT17. The first electrode of the first pixel SP1 may be located in the third electrode layer, and the seventeenth contact hole CNT17 may be formed through the via layer VIA.

The second transistor ST2 of the first pixel SP1 may include an active area ACT2, a gate electrode GE2, a drain electrode DE2, and a source electrode SE2. The active area ACT2 of the second transistor ST2 may be located in the active layer ACTL, and may overlap with the gate electrode GE2 of the second transistor ST2 in the thickness direction (z-axis direction).

The gate electrode GE2 of the second transistor ST2 may be located in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be connected to the first data line DL1 through the second connection electrode BE2. The drain electrode DE2 of the second transistor ST2 may receive a data voltage of the first pixel SP1 from the first data line DL1.

The source electrode SE2 of the second transistor ST2 may be formed integrally with the first capacitor electrode CPE1 of the first capacitor C1. The source electrode SE2 of the second transistor ST2 may be connected to the gate electrode GE1 of the first transistor ST1 through the first capacitor electrode CPE1.

The third transistor ST3 of the first pixel SP1 may include an active area ACT3, a gate electrode GE3, a drain electrode DE3, and a source electrode SE3. The active area ACT3 of the third transistor ST3 may be located in the active layer ACTL, and may overlap with the gate electrode GE3 of the third transistor ST3 in the thickness direction (z-axis direction).

The gate electrode GE3 of the third transistor ST3 may be located at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode DE3 of the third transistor ST3 may be connected to the initialization voltage line VIL through the third connection electrode BE3. The drain electrode DE3 of the third transistor ST3 may receive an initialization voltage from the initialization voltage line VIL. The drain electrode DE3 of the third transistor ST3 may supply a sensing signal to the initialization voltage line VIL.

The source electrode SE3 of the third transistor ST3 may be connected to the source electrode SE1 of the first transistor ST1 and the second capacitor electrode CPE2 through the fourth connection electrode BE4.

The pixel circuit of the second pixel SP2 may include the first to third transistors ST1, ST2, and ST3. The first transistor ST1 of the second pixel SP2 may include an active area ACT1, a gate electrode GE1, a drain electrode DE1, and a source electrode SE1. The active area ACT1 of the first transistor ST1 may be located in the active layer ACTL, and may overlap with the gate electrode GE1 of the first transistor ST1 in the thickness direction (z-axis direction).

The gate electrode GE1 of the first transistor ST1 may be located in the second metal layer MTL2. The gate electrode GE1 of the first transistor ST1 may be connected to the first capacitor electrode CPE1 of the first capacitor C1 located in the active layer ACTL through an eighth contact hole CNT8. The first capacitor electrode CPE1 of the first capacitor C1 may be formed into a conductor by heat-treating the active layer ACTL. The first capacitor electrode CPE1 of the first capacitor C1 may be formed integrally with the source electrode SE2 of the second transistor ST2, but the present disclosure is not limited thereto.

The drain electrode DE1 and the source electrode SE1 of the first transistor ST1 may be formed into a conductor by heat-treating the active layer ACTL. The fifteenth connection electrode BE15 may connect the first voltage line VDL with the drain electrode DE1 of the first transistor ST1 through the sixth contact hole CNT6. The drain electrode DE1 of the first transistor ST1 may receive a driving voltage from the first voltage line VDL.

A ninth connection electrode BE9 of the second metal layer MTL2 may connect the source electrode SE1 of the first transistor ST1, the source electrode SE3 of the third transistor ST3, and the second capacitor electrode CPE2 of the first metal layer MTL1 through a seventh contact hole CNT7. The first capacitor C1 may be formed between the first capacitor electrode CPE1 of the active layer ACTL and the second capacitor electrode CPE2 of the first metal layer MTL1.

A tenth connection electrode BE10 of the second metal layer MTL2 may be connected to the second capacitor electrode CPE2 through an eighteenth contact hole CNT18. The tenth connection electrode BE10 may be connected to the first electrode of the first pixel SP1 through a nineteenth contact hole CNT19. The first electrode of the first pixel SP1 may be located in the third electrode layer, and the nineteenth contact hole CNT19 may be formed through the via layer VIA.

The second transistor ST2 of the second pixel SP2 may include an active area ACT2, a gate electrode GE2, a drain electrode DE2, and a source electrode SE2. The active area ACT2 of the second transistor ST2 may be located in the active layer ACTL, and may overlap with the gate electrode GE2 of the second transistor ST2 in the thickness direction (z-axis direction).

The gate electrode GE2 of the second transistor ST2 may be located in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be connected to the second data line DL2 through the seventh connection electrode BE7. The drain electrode DE2 of the second transistor ST2 may receive a data voltage of the second pixel SP2 from the second data line DL2.

The source electrode SE2 of the second transistor ST2 may be formed integrally with the first capacitor electrode CPE1 of the first capacitor C1. The source electrode SE2 of the second transistor ST2 may be connected to the gate electrode GE1 of the first transistor ST1 through the first capacitor electrode CPE1.

The third transistor ST3 of the second pixel SP2 may include the active area ACT3, the gate electrode GE3, the drain electrode DE3, and the source electrode SE3. The active area ACT3 of the third transistor ST3 may be located in the active layer ACTL, and may overlap with the gate electrode GE3 of the third transistor ST3 in the thickness direction (z-axis direction).

The gate electrode GE3 of the third transistor ST3 may be located at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode DE3 of the third transistor ST3 may be connected to the initialization voltage line VIL through the eighth connection electrode BE8. The drain electrode DE3 of the third transistor ST3 may receive an initialization voltage from the initialization voltage line VIL. The drain electrode DE3 of the third transistor ST3 may supply a sensing signal to the initialization voltage line VIL.

The source electrode SE3 of the third transistor ST3 may be connected to the source electrode SE1 of the first transistor ST1 and the second capacitor electrode CPE2 through the ninth connection electrode BE9.

The pixel circuit of the third pixel SP3 may include the first to third transistors ST1, ST2, and ST3. The first transistor ST1 of the third pixel SP3 may include the active area ACT1, the gate electrode GE1, the drain electrode DE1 and the source electrode SE1. The active area ACT1 of the first transistor ST1 may be located in the active layer ACTL, and may overlap with the gate electrode GE1 of the first transistor ST1 in the thickness direction (z-axis direction).

The gate electrode GE1 of the first transistor ST1 may be located in the second metal layer MTL2. The gate electrode GE1 of the first transistor ST1 may be connected to the first capacitor electrode CPE1 of the first capacitor C1 located in the active layer ACTL through a thirteenth contact hole CNT13. The first capacitor electrode CPE1 of the first capacitor C1 may be formed into a conductor by heat-treating the active layer ACTL. The first capacitor electrode CPE1 of the first capacitor Cl may be formed integrally with the source electrode SE2 of the second transistor ST2, but the present disclosure is not limited thereto.

The drain electrode DE1 and the source electrode SE1 of the first transistor ST1 may be formed into a conductor by heat-treating the active layer ACTL. The fifteenth connection electrode BE15 may connect the first voltage line VDL with the drain electrode DE1 of the first transistor ST1 through the eleventh contact hole CNT11. The drain electrode DE1 of the first transistor ST1 may receive a driving voltage from the first voltage line VDL.

A thirteenth connection electrode BE13 of the second metal layer MTL2 may connect the source electrode SE1 of the first transistor ST1, the source electrode SE3 of the third transistor ST3, and the second capacitor electrode CPE2 of the first metal layer MTL1 through the twelfth contact hole CNT12. The first capacitor C1 may be formed between the first capacitor electrode CPE1 of the active layer ACTL and the second capacitor electrode CPE2 of the first metal layer MTL1.

A fourteenth connection electrode BE14 of the second metal layer MTL2 may be connected to the second capacitor electrode CPE2 through a twentieth contact hole CNT20. The fourteenth connection electrode BE14 may be connected to the first electrode of the first pixel SP1 through a twenty-first contact hole CNT21. The first electrode of the first pixel SP1 may be located in the third electrode layer, and the twenty-first contact hole CNT21 may be formed through the via layer VIA.

The second transistor ST2 of the third pixel SP3 may include the active area ACT2, the gate electrode GE2, the drain electrode DE2, and the source electrode SE2. The active area ACT2 of the second transistor ST2 may be located in the active layer ACTL, and may overlap with the gate electrode GE2 of the second transistor ST2 in the thickness direction (z-axis direction).

The gate electrode GE2 of the second transistor ST2 may be located in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be connected to the third data line DL3 through the twelfth connection electrode BE12. The drain electrode DE2 of the second transistor ST2 may receive a data voltage of the third pixel SP3 from the third data line DL3.

The source electrode SE2 of the second transistor ST2 may be formed integrally with the first capacitor electrode CPE1 of the first capacitor C1. The source electrode SE2 of the second transistor ST2 may be connected to the gate electrode GE1 of the first transistor ST1 through the first capacitor electrode CPE1.

The third transistor ST3 of the third pixel SP3 may include the active area ACT3, the gate electrode GE3, the drain electrode DE3, and the source electrode SE3. The active area ACT3 of the third transistor ST3 may be located in the active layer ACTL, and may overlap with the gate electrode GE3 of the third transistor ST3 in the thickness direction (z-axis direction).

The gate electrode GE3 of the third transistor ST3 may be located at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode DE3 of the third transistor ST3 may be connected to the initialization voltage line VIL through the eighth connection electrode BE8. The drain electrode DE3 of the third transistor ST3 may receive an initialization voltage from the initialization voltage line VIL. The drain electrode DE3 of the third transistor ST3 may supply a sensing signal to the initialization voltage line VIL.

The source electrode SE3 of the third transistor ST3 may be connected to the source electrode SE1 of the first transistor ST1 and the second capacitor electrode CPE2 through the thirteenth connection electrode BE13.

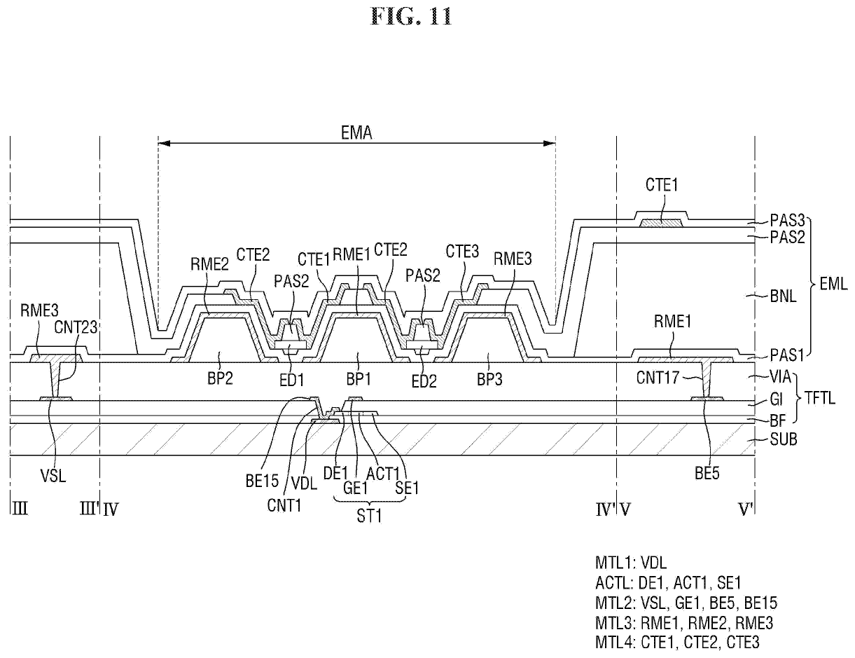

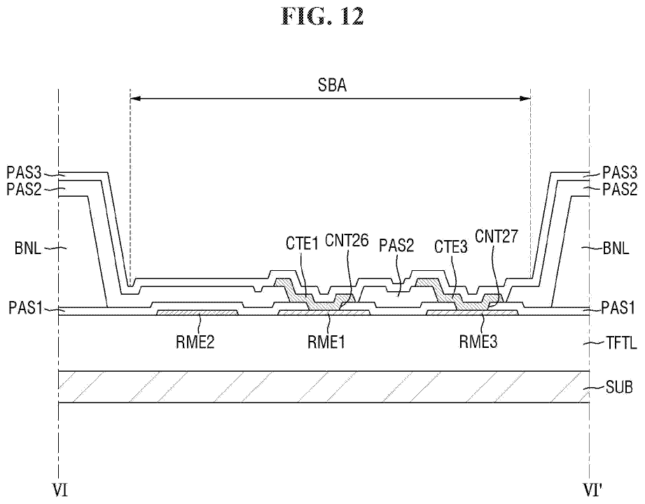

FIG. 10 is a plan view showing an emission material layer of a display device according to one or more embodiments of the present disclosure. FIG. 11 is a cross-sectional view taken along the lines III-III′, IV-IV′, and V-V′ of FIG. 10. FIG. 12 is a cross-sectional view taken along the line VI-VI′ of FIG. 10.

Referring to FIGS. 10 to 12, the emission material layer EML of the display device 10 may be located on a thin-film transistor layer TFTL. The emission material layer EML may include first to third bank patterns BP1, BP2, and BP3, first to third electrodes RME1, RME2, and RME3, first and second light-emitting elements ED1 and ED2, a first insulating film PAS1, a bank layer BNL, a second insulating film PAS2, first to third contact electrodes CTE1, CTE2, and CTE3, and a third insulating film PAS3.

The first bank pattern BP1 may be located at the center in an emission area EMA, the second bank pattern BP2 may be located on the left side in the emission area EMA, and the third bank pattern BP3 may be located on the right side in the emission area EMA. Each of the first to third bank patterns BP1, BP2, and BP3 may protrude upwardly (in the z-axis direction) on the via layer VIA. Each of the first to third bank patterns BP1, BP2, and BP3 may have inclined side surfaces. The plurality of first light-emitting elements ED1 may be located between the first and second bank patterns BP1 and BP2 spaced apart from each other, and the plurality of second light-emitting elements ED2 may be located between the second and third bank patterns BP2 and BP3 spaced apart from each other. The first to third bank patterns BP1, BP2, and BP3 may have the same length in the second direction (y-axis direction) and different lengths in the first direction (x-axis direction), but the present disclosure is not limited thereto. The first to third bank patterns BP1, BP2, and BP3 may be located as island-shaped patterns on the front surface of the display area DA.

The first to third electrodes RME1, RME2, and RME3 of the first to third pixels SP1, SP2, and SP3 may be located in the third electrode layer MTL3. The third electrode layer MTL3 may be located on the via layer VIA and the first to third bank patterns BP1, BP2, and BP3. The first electrode RME1 may extend in the second direction (y-axis direction) at the center of the emission area EMA. The first electrode RME1 may cover the upper surface and inclined side surfaces of the first bank pattern BP1. Accordingly, the first electrode RME1 may reflect the lights emitted from the first and second light-emitting elements ED1 and ED2 upward (in the z-axis direction).

The second electrode RME2 may extend in the second direction (y-axis direction) on the left side in the emission area EMA. The second electrode RME2 may cover the upper surface and inclined side surfaces of the second bank pattern BP2. Accordingly, the second electrode RME1 may reflect the lights emitted from the first light-emitting elements ED1 upward (in the z-axis direction).

The third electrode RME3 may extend in the second direction (y-axis direction) on the right side in the emission area EMA. The third electrode RME3 may cover the upper surface and inclined side surfaces of the third bank pattern BP3. Accordingly, the third electrode RME3 may reflect the lights emitted from the second light-emitting elements ED2 upward (in the z-axis direction).

Respective ends of the first to third electrodes RME1, RME2, and RME3 in a row may be separated from those in another row at a separation region ROP. The first to third electrodes RME1, RME2, and RME3 may be alignment electrodes that align the first and second light-emitting elements ED1 and ED2 during the process of fabricating the display device 10. Before the first electrode RME1 is separated, the first electrode RME1 might be connected to the horizontal voltage line HVDL of the second metal layer MTL2 through a twenty-second contact hole CNT22 and might receive a driving voltage or a high-level voltage to work as the alignment electrode. Accordingly, the first to third electrodes RME1, RME2, and RME3 may be separated at the separation region ROP after the alignment process of the plurality of light-emitting devices ED has been completed.

The first electrode RME1 of the first pixel SP1 may be connected to the fifth connection electrode BE5 of the second metal layer MTL2 through the seventeenth contact hole CNT17. The first electrode RME1 may receive the driving current passing through the first transistor ST1 from the fifth connection electrode BE5. The first electrode RME1 may supply a driving current to the plurality of first light-emitting elements ED1 of the first pixel SP1 through the first contact electrode CTE1.

The third electrode RME3 of the first pixel SP1 may be connected to the second voltage line VSL of the second metal layer MTL2 through the twenty-third contact hole CNT23. Accordingly, the third electrode RME3 of the first pixel SP1 may receive the low-level voltage from the second voltage line VSL.

The first electrode RME1 of the second pixel SP2 may be connected to the tenth connection electrode BE10 of the second metal layer MTL2 through the nineteenth contact hole CNT19. The first electrode RME1 may receive the driving current passing through the first transistor ST1 from the tenth connection electrode BE10. The first electrode RME1 may supply a driving current to the plurality of first light-emitting elements ED1 of the second pixel SP2 through the first contact electrode CTE1.

The third electrode RME3 of the second pixel SP2 may be connected to the second voltage line VSL of the second metal layer MTL2 through the twenty-fourth contact hole CNT24. Accordingly, the third electrode RME3 of the second pixel SP2 may receive the low-level voltage from the second voltage line VSL.

The first electrode RME1 of the third pixel SP3 may be connected to the fourteenth connection electrode BE14 of the second metal layer MTL2 through the twenty-first contact hole CNT21. The first electrode RME1 may receive the driving current passing through the first transistor ST1 from the fourteenth connection electrode BE14. The first electrode RME1 may supply a driving current to the plurality of first light-emitting elements ED1 of the third pixel SP3 through the first contact electrode CTE1.

The third electrode RME3 of the third pixel SP3 may be connected to the second voltage line VSL of the second metal layer MTL2 through the twenty-fifth contact hole CNT25. Accordingly, the third electrode RME3 of the third pixel SP3 may receive the low-level voltage from the second voltage line VSL.

The plurality of first light-emitting elements ED1 may be aligned between the first electrode RME1 and the second electrode RME2. The first insulating film PAS1 may cover the first to third electrodes RME1, RME2, and RME3. The first light-emitting elements ED1 may be insulated from the first and second electrodes RME1 and RME2 by the first insulating film PAS1. Before the first and second electrodes RME1 and RME2 are cut at the separation region ROP, each of the first and second electrodes RME1 and RME2 may receive an alignment signal, and an electric field may be formed between the first and second electrodes RME1 and RME2. For example, the first light-emitting diodes ED1 may be ejected onto the first and second electrodes RME1 and RME2 via an inkjet printing process. The first light-emitting diodes ED1 dispersed in the ink may be aligned by receiving a dielectrophoresis force by the electric field formed between the first and second electrodes RME1 and RME2. Accordingly, the plurality of first light-emitting elements ED1 may be aligned in the first direction (x-axis direction) between the first and second electrodes RME1 and RME2.

The plurality of second light-emitting elements ED2 may be aligned between the first electrode RME1 and the third electrode RME3. The second light-emitting elements ED2 may be insulated from the first and third electrodes RME1 and RME3 by the first insulating film PAS1. Before the first and third electrodes RME1 and RME3 are cut at the separation region ROP, each of the first and third electrodes RME1 and RME3 may receive an alignment signal, and an electric field may be formed between the first and third electrodes RME1 and RME3. For example, the second light-emitting elements ED2 may be ejected onto the first and third electrodes RME1 and RME3 via an inkjet printing process. The second light-emitting elements ED2 dispersed in the ink may be aligned by receiving a dielectrophoresis force by the electric field formed between the first and third electrodes RME1 and RME3. Accordingly, the plurality of second light-emitting elements ED2 may be aligned in the first direction (x-axis direction) between the first and third electrodes RME1 and RME3.

The first to third contact electrodes CTE1, CTE2, and CTE3 of each of the first to third pixels SP1, SP2, and SP3 may be located on the first to third electrodes RME1, RME2, and RME3. The second insulating film PAS2 may be located on the bank layer BNL, the first insulating film PAS1, and the central portion of the light-emitting elements ED. The third insulating film PAS3 may cover the second insulating film PAS2 and the first to third contact electrodes CTE1, CTE2, and CTE3. The second and third insulating films PAS2 may insulate each of the first to third contact electrodes CTE1, CTE2, and CTE3.

The first contact electrode CTE1 may be located on the first electrode RME1 and may be connected to the first electrode RME1 through a twenty-sixth contact hole CNT26. The first contact electrode CTE1 may be connected between the first electrode RME1 and one ends/first ends of the plurality of first light-emitting elements ED1. The first contact electrode CTE1 may correspond to the anode electrode of the plurality of first light-emitting elements ED1, but the present disclosure is not limited thereto.

The second contact electrode CTE2 may be located on the first and second electrodes RME1 and RME2, and may be insulated from the first and second electrodes RME1 and RME2. A first portion of the second contact electrode CTE2 may be located on the second electrode RME2 and may extend in the second direction (y-axis direction). A second portion of the second contact electrode CTE2 may be bent from the lower side of the first portion to extend in the first direction (x-axis direction). A third portion of the second contact electrode CTE2 may be bent from the right side of the second portion to extend in the second direction (y-axis direction), and may be located on the first electrode RME1.

The second contact electrode CTE2 may be connected between the other ends/second ends of the plurality of first light-emitting elements ED1 and the one ends/first ends of the plurality of second light-emitting elements ED2. The second contact electrode CNE2 may correspond to the third node N3 of FIG. 4. The second contact electrode CTE2 may correspond to the cathode electrode of the plurality of first light-emitting elements ED1, but the present disclosure is not limited thereto. The second contact electrode CTE2 may correspond to the anode electrode of the plurality of second light-emitting elements ED2, but the present disclosure is not limited thereto.

The third contact electrode CTE3 may be located on the third electrode RME3 and may be connected to the third electrode RME3 through a twenty-seventh contact hole CNT27. The third contact electrode CTE3 may be connected between the other ends/second ends of the plurality of second light-emitting elements ED2 and the third electrode RME3. The third contact electrode CTE3 may correspond to the cathode electrode of the plurality of second light-emitting elements ED2, but the present disclosure is not limited thereto. The third contact electrode CTE3 may receive a low-level voltage through the third electrode RME3.

The first transistor ST1 of the thin-film transistor TFTL may include an active area ACT1, a gate electrode GE1, a drain electrode DE1, and a source electrode SE1. The drain electrode DE1 of the first transistor ST1 may receive a driving voltage from the first voltage line VDL of the first electrode layer BML through the fifteenth connection electrode BE15.

Although the above description focuses on a display apparatus, the disclosure is not limited thereto. For example, a method of manufacturing the above display apparatus may belong to the scope of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
first and second unit pixels adjacent to each other in a first direction, and each comprising first to third pixels;
a first voltage line on a first side of each of the first and second unit pixels, and extended in a second direction crossing the first direction;
a data line on a second side of each of the first and second unit pixels, and extended in the second direction;
first gate lines between the first side of the first unit pixel and the second side of the second unit pixel to not be on the second side of the first unit pixel and to not be on the first side of the second unit pixel, and extended in the second direction; and
a second gate line connected to at least one of the first gate lines, and extended in the first direction.

2. The display device of claim 1, wherein a number of first gate lines between the first unit pixel and the second unit pixel is an odd number equal to or greater than three.

3. The display device of claim 1, wherein the first gate lines are between the first voltage line connected to the first unit pixel and the data line connected to the second unit pixel.

4. The display device of claim 1, further comprising third and fourth unit pixels arranged adjacent to each other in the first direction on the second side of the first unit pixel or on the first side of the second unit pixel,
wherein other first gate lines are between a first side of the third unit pixel and a second side of the fourth unit pixel.

5. The display device of claim 4, wherein the first gate lines and the other first gate lines are not between the second and third unit pixels.

6. The display device of claim 4, wherein a number of the other first gate lines between the third unit pixel and the fourth unit pixel is an odd number equal to or greater than three.

7. The display device of claim 1, further comprising an auxiliary gate line extended from the second gate line in the second direction and configured to supply a gate signal to the first to third pixels.

8. The display device of claim 7, further comprising an initialization voltage line extended in the second direction between the auxiliary gate line and the data line and configured to supply an initialization voltage to the first to third pixels.

9. The display device of claim 8, wherein each of the first to third pixels comprises:
a light-emitting element;
a first transistor between the first voltage line and the light-emitting element, and configured to supply a driving current to the light-emitting element;
a second transistor configured to connect the data line with a first node coupled to a gate electrode of the first transistor based on the gate signal;
a third transistor configured to connect the initialization voltage line with a second node coupled to a source electrode of the first transistor based on the gate signal; and
a first capacitor connected between the first and second nodes.

10. The display device of claim 9, further comprising:
a vertical voltage line on a second side of the data line, and extended in the second direction; and
a second voltage line connected to the vertical voltage line, extended in the first direction, and configured to supply a low-level voltage to the light-emitting element.

11. A display device comprising:
first and second unit pixels adjacent to each other in a first direction, and each comprising first to third pixels;
a first voltage line in a first metal layer to extend in a second direction crossing the first direction, and configured to supply a driving voltage to the first to third pixels;
a data line extended in the second direction in the first metal layer;
first gate lines in the first metal layer, extended in the second direction between the first and second unit pixels, and not located on a first side of the second unit pixel that is not adjacent to the first unit pixel; and
a second gate line in a second metal layer above the first metal layer, and extended in the first direction.

12. The display device of claim 11, further comprising:
an auxiliary gate line extended from the second gate line in the second direction, and configured to supply gate signals to the first to third pixels; and
an initialization voltage line extended in the first metal layer in the second direction, and configured to supply an initialization voltage to the first to third pixels.

13. The display device of claim 12, wherein each of the first to third pixels comprises:
a light-emitting element;
a first transistor between the first voltage line and the light-emitting element, and configured to supply a driving current to the light-emitting element;
a second transistor configured to connect the data line with a first node that is connected to a gate electrode of the first transistor based on one of the gate signals;
a third transistor configured to connect the initialization voltage line with a second node that is connected to a source electrode of the first transistor based on one of the gate signals; and
a first capacitor connected between the first and second nodes.

14. The display device of claim 13, wherein a gate electrode of each of the second and third transistors corresponds to a portion of the auxiliary gate line.

15. The display device of claim 13, wherein each of the first to third transistors comprises an active area, a drain electrode, a source electrode, and a gate electrode,
wherein the active area, the drain electrode, and the source electrode are in an active layer between the first and second metal layers, and
wherein the gate electrode is in the second metal layer.

16. The display device of claim 15, wherein the first capacitor comprises:
a first capacitor electrode on the active layer, and connected to the first node; and
a second capacitor electrode on the first metal layer, and connected to the second node.

17. The display device of claim 13, further comprising first and second electrodes extended in the second direction in a third metal layer above the second metal layer,
wherein the light-emitting element is aligned between the first and second electrodes when viewed from top.

18. The display device of claim 17, further comprising a connection electrode in the second metal layer, and connected between the second node and the first electrode.

19. The display device of claim 17, further comprising a second voltage line extended in the first direction in the second metal layer,
wherein the second electrode is configured to receive a low-level voltage from the second voltage line.

20. The display device of claim 17, further comprising:
a first contact electrode in a fourth metal layer above the third metal layer, and connected between a first end of the light-emitting element and the first electrode; and
a second contact electrode in the fourth metal layer, and connected between a second end of the light-emitting element and the second electrode.
